(19) United States
(12) Patent Application Publication
(10) Pub. No.: US 2007/0206398 A1
(43) Pub. Date: Sep. 6, 2007

(54) SEMICONDUCTOR MEMORY

(76) Inventors: Dai Nakamura, Kawasaki-shi (JP); Koji Hosono, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/681,944

(22) Filed: Mar. 5, 2007

(30) Foreign Application Priority Data
Mar. 6, 2006 (JP) 2006-059659

(51) Int. Cl. G11C 16/04; G11C 5/02; G11C 16/06; G11C 11/34

(52) U.S. Cl. 365/51; 365/185.17; 365/185.23

(57) ABSTRACT

A semiconductor memory according to an example of the present invention is provided with a memory cell array, a plurality of word lines provided on the memory cell array, and a plurality of transfer transistors each one of which is connected to each of the plurality of word lines. Direction of one of the plurality of transfer transistors is different from direction of another one of the transfer transistors.

### CROSS-REFERENCE TO RELATED APPLICATIONS

This application is based upon and claims the benefit of priority from prior Japanese Patent Application No. 2006-059659, filed Mar. 6, 2006, the entire contents of which are incorporated herein by reference.

### BACKGROUND OF THE INVENTION

1. Field of the Invention

The present invention relates to a layout of a transfer transistor in a word line driver of a semiconductor memory.

2. Description of the Related Art

Shrink of memory cells is crucial to increasing semiconductor memory capacity. Since NAND-type flash memories are now being used for main storage in compact and lightweight electronic devices, progress is being made in miniaturizing memory cells to realize the increased memory capacity needed to support device multi-functionality.

While memory cell size has decreased, a word line driver cannot be made as small as a memory cell since the driver size is limited by the magnitude of voltage transferred to the word line.

Therefore, the layout of a word line driver in a memory cell array becomes important from the point of view of simplifying connection between a word line and the word line driver, and reducing chip size (For instance, refer to JP-A 2002-141477 [KOKAI] and JP-A 2005-39016 [KOKAI]).

### BRIEF SUMMARY OF THE INVENTION

A semiconductor memory according to an aspect of the present invention is provided with a memory cell array, a plurality of word lines arranged on the memory cell array, and a plurality of transfer transistors each one of which is connected to each of the plurality of word lines and which transfer a transfer voltage, wherein direction of one of the plurality of transfer transistors is different from direction of another one of the transfer transistors.

### BRIEF DESCRIPTION OF THE SEVERAL VIEWS OF THE DRAWING

FIG. 1 is a block diagram showing a NAND-type flash memory;

FIG. 2 is a view showing position relationship between a memory cell array and a word line driver;

FIG. 3 is a view showing a layout of a cell unit;

FIG. 4 is a view showing a cross section in a column direction of the cell unit;

FIG. 5 is a view showing a layout as a reference example;

FIG. 6 is a view showing a layout as a reference example;

FIG. 7 is a view showing a layout as a first embodiment;

FIG. 8 is a view showing a layout of a conductive line introducing a transfer voltage;

FIG. 9 is a view showing a channel length, a channel width and a width of an element isolation insulating layer;

FIG. 10 is a cross-sectional view along X-X line of FIG. 9;

FIG. 11 is a cross-sectional view along XI-XI line of FIG. 9;

FIG. 12 is a view showing a layout as a second embodiment;

FIG. 13 is a view showing a layout as a third embodiment;

FIG. 14 is a view showing position relationship between a memory cell array and a word line driver;

FIG. 15 is a view showing a layout as a fourth embodiment;

FIG. 16 is a view showing a layout of a conductive line introducing a transfer voltage;

FIG. 17 is a view showing a layout as a fifth embodiment; and

FIG. 18 is a view showing a layout as a sixth embodiment.

### DETAILED DESCRIPTION OF THE INVENTION

A semiconductor memory of an aspect of the present invention will be described with reference to the accompanying drawings.

### 1. OUTLINE

In an example of the present invention, there are provided a plurality of transfer transistors each one of which is connected to each of a plurality of word lines and which transfer a transfer voltage, and there is adopted a layout in which direction of one of the transfer transistors is different from direction of another one transfer transistor.

That is, there are mixed a transfer transistor whose transfer path of the transfer voltage is a first direction and a transfer transistor whose transfer path of the transfer voltage is a second direction which crosses the first direction.

According to such layout, in comparison with the case where all directions of a plurality of transfer transistors are the same, it is possible to simplify connection between the word line and the word line driver, and to reduce the chip size.

In the case where the example of the present invention is applied to the NAND-type flash memory, for instance, by using two kinds of transfer transistors in which direction of one transistor is different from direction of another one transistor by 90°, it becomes possible to repeat pattern of a plurality of transfer transistors and the conductive lines connecting the plurality of transfer transistors and a plurality of word lines with a short period.

### 2. EMBODIMENTS

There will be described embodiments using a NAND-type flash memory as an example.

### (1) Total View

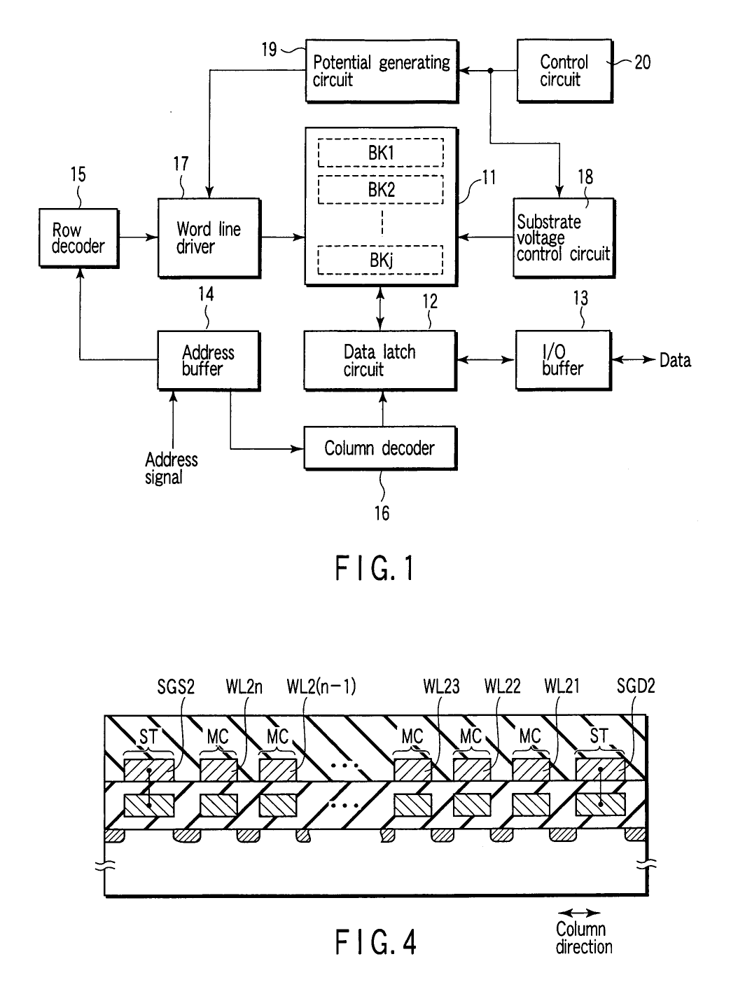

FIG. 1 shows a total view of the NAND-type flash memory.

A memory cell array 11 is comprised a plurality of blocks BK1, BK2, . . . , BLj. Each of the plurality of blocks BK1, BK2, . . . , BLj has a plurality of cell units, and each of the plurality of cell units is comprised a NAND string comprised a plurality of memory cells connected serially and two select gate transistors connected to both ends of the memory cell.

A data latch circuit 12 which has a function to latch data temporarily at the time of read/write, is comprised, for instance, a flip-flop circuit. An input/output (I/O) buffer 13 functions as an interface circuit of the data, and an address buffer 14 functions as an interface circuit of an address signal.

A row decoder 15 and a column decoder 16 select the memory cell in the memory cell array 11 based on the address signal. A word line driver 17 drives a selected word line in a selected block.

A substrate voltage control circuit 18 controls voltage of a semiconductor substrate. Specifically, a double well region comprised a n-type well region and a p-type well region is formed in a p-type semiconductor substrate, and when the memory cell is formed in the p-type well region, voltage of the p-type well region is controlled in accordance with an operation mode.

For instance, the substrate voltage control circuit 18 sets the p-type well region to 0 V at the time of read/write, and sets the p-type well region to a voltage of 15 V or more to 40 V or less at the time of erase.

A potential generating circuit 19 generates a transfer voltage. The transfer voltage is supplied to a word line in the selected block via the word line driver 17.

For instance, at the time of read, the potential generating circuit 19 generates a read voltage and an intermediate voltage. The read voltage is supplied to the selected word line in the selected block via the word line driver 17, and the intermediate voltage is supplied to a non-selected word line in the selected block via the word line driver 17.

Further, at the time of write, the potential generating circuit 19 generates a write voltage and an intermediate voltage. The write voltage is supplied to the selected word line in the selected block via the word line driver 17, and the intermediate voltage is supplied to the non-selected word line in the selected block via the word line driver 17.

A control circuit 20 controls operation of, for instance, the substrate voltage control circuit 18 and the potential generating circuit 19.

### (2) Memory Cell Array and Word Line Driver

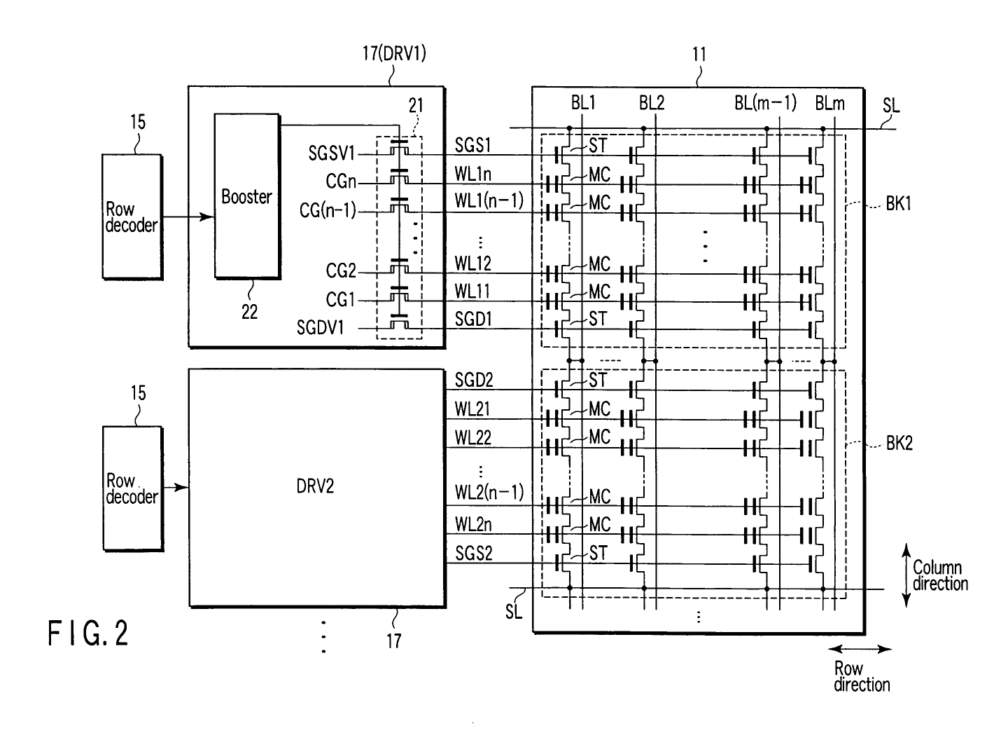

FIG. 2 shows a memory cell array and a word line driver of the NAND-type flash memory.

The memory cell array 11 is comprised a plurality of blocks BK1, BK2, . . . arranged in a column direction.

Each of the blocks has a plurality of cell units arranged in a row direction. Each of the plurality of cell units is comprised a NAND string comprised a plurality of memory cells MC connected serially, and two select gate transistors ST connected to both ends of the memory cell.

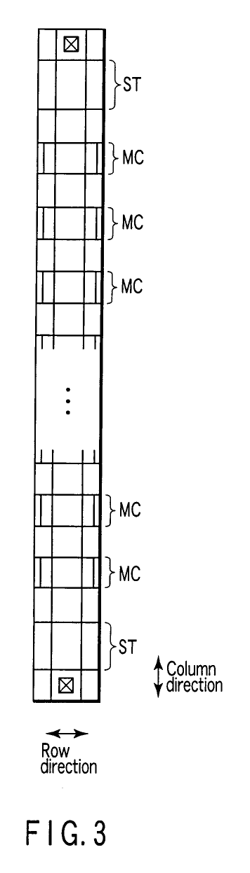

The cell unit has a layout, for instance, as shown in FIG. 3. A cross-sectional structure in the column direction of the cell unit is the structure, for instance, as shown in FIG. 4.

One end of the cell unit is connected to bit lines BL1, BL2, . . . , BLm and the other end thereof is connected to a source line SL.

On the memory cell array 11, a plurality of word lines WL11, . . . , WL1n, . . . and a plurality of selection gate lines SGS1, SGD1, . . . are arranged.

For instance, in the block BK1, n word lines WL11, . . . , WL1n and 2 selection gate lines SGS1, SGD1 are arranged. The word lines WL11, . . . , WL1n and the selection gate lines SGS1, SGD1 extend in the row direction, and are connected to conductive lines CG1, . . . , CGn, SGSV1, SGDV1 respectively via a transfer transistor unit 21 in the word line driver 17 (DRV1).

The transfer transistor unit 21 is comprised a high voltage type MISFET so as to be able to transfer higher transfer voltage than a source voltage Vcc.

A booster 22 in the word line driver 17 (DRV1) receives a decode signal output from the row decoder 15. The booster 22, when the block BK1 is selected, turns the transfer transistor unit 21 on, while when the block BK1 is not selected, turns the transfer transistor unit 21 off.

Here, in the case of the NAND-type flash memory, increasing the number of the memory cells constituting one NAND string is the simplest and convenient way to achieve increase of the memory capacity. However, increasing the number of the memory cells constituting the NAND string means increasing the number of the word lines in one block.

On the other hand, one transfer transistor is connected to one word line. The size of the transfer transistor, as already described, is limited by magnitude of the transfer voltage transferred to the word line, and thus inevitably becomes larger than the size of the memory cell.

Therefore, it is impossible to arrange the transfer transistor in a line simply corresponding to a plurality of word lines in one block, and how layout of the word line driver is executed on a memory cell array becomes important, in order to simplify connection between the word line and the word line driver, and to reduce chip size.

### (3) Reference Example

First, there will be explained a reference example.

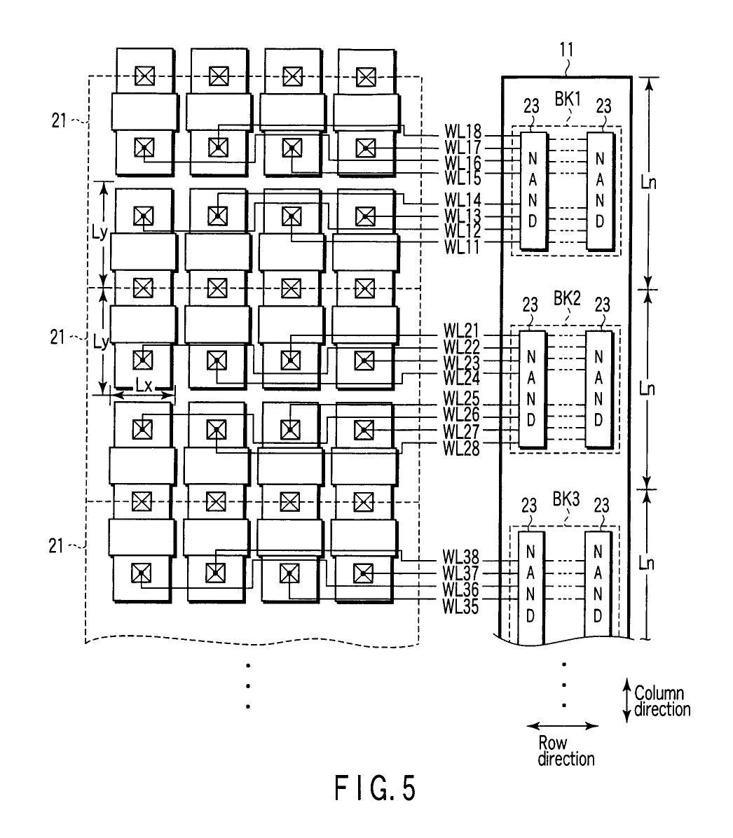

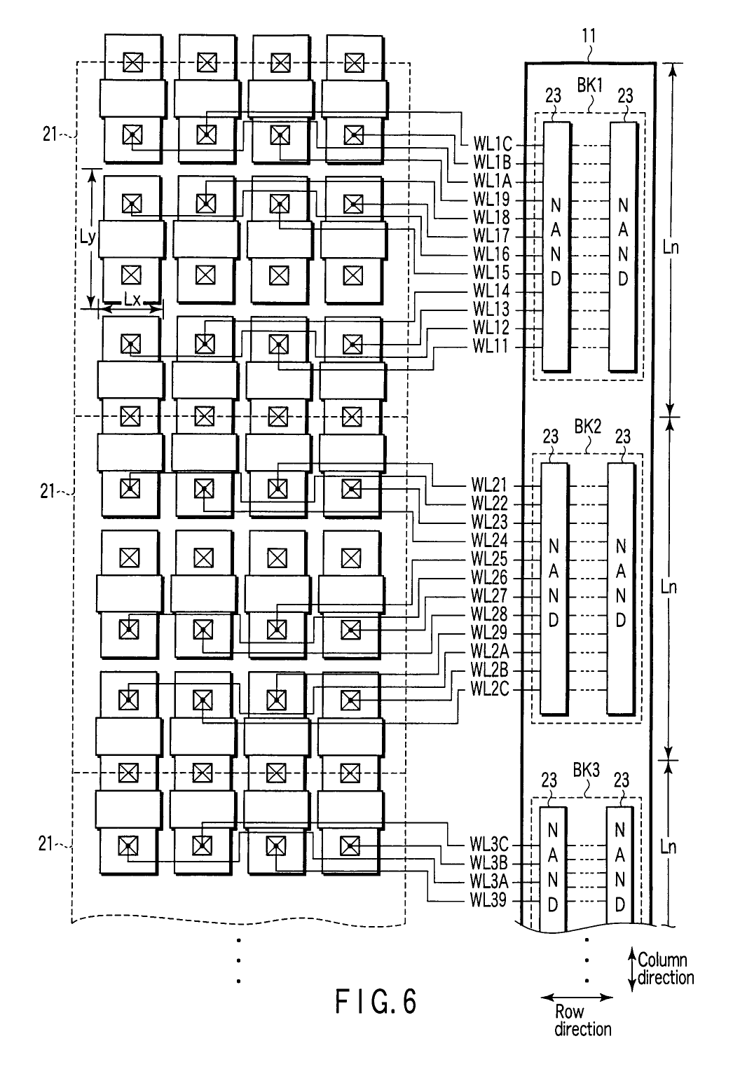

FIGS. 5 and 6 show a layout of the transfer transistor in the word line driver as the reference example.

A NAND string 23 is comprised a plurality of memory cells connected serially. In the example of FIG. 5, the NAND string is comprised 8 memory cells, and 8 word lines exist in one block. Further, in the example of FIG. 6, the NAND string is comprised 12 memory cells, and 12 word lines exist in one block.

At one end side of the memory cell array 11, the transfer transistor unit 21 is arranged corresponding to the blocks BK1, BK2, . . . The transfer transistor unit 21 is comprised MISFET and all directions thereof are the same. That is, the transfer transistor is arranged with a layout in which the transfer path (channel length direction) of the transfer voltage is in the column direction.

In the example of FIG. 5, the transfer transistor unit 21 is comprised the 8 transfer transistors arranged with 2 rows×4 columns. In the example of FIG. 6, the transfer transistor unit 21 is comprised the 12 transfer transistors arranged with 3 rows×4 columns.

Characteristic of the layout lies in the point that, for instance, the transfer transistors connected to the word lines WL11, WL12, WL13 and WL14 in the block BK1, and the transfer transistors connected to the word lines WL21, WL22, WL23 and WL24 in the block BK2 share a diffusion layer.

In this manner, the size in the column direction per one transfer transistor decreases, resulting in decreasing the occupied area in the chip of the word line driver.

Here, a significant point is that, in order to reduce the chip size, not only the size in the column direction per one transfer transistor is simply made small, but also the pattern of the conductive line connecting the transfer transistor to the word line repeated with a short period.

In order to achieve the above object, in the case where the size in the column direction of one block is defined as Ln, the size of the channel width direction of the transfer transistor is defined as Lx, and the size of the channel length direction is defined as Ly, it is necessary to obtain natural numbers s, t, which are small as possible, and sLn which is as close to tLy as possible on the assumption of fulfilling (t+1)Ly≧sLn≧tLy.

That is, the closer to tLy sLn is, the less there exists wasteful space, and further, the smaller the natural numbers s, t are, the more it is likely that the pattern of the conductive line connecting the transfer transistor to the word line can be repeated with a short period, so that it is possible to simplify connection between the transfer transistor and the word line.

However, the size Ln in the column direction of one block and the size Lx×Ly of the transfer transistor are frequently determined independently. Further, other factors, such as for instance, width of the element isolation insulating layer, the layout of the conductive line introducing the transfer voltage from the potential generating circuit to the transfer transistor, or the like should be taken into consideration. Therefore, it is difficult to obtain ideal natural numbers s, t.

Generally, the value of the natural numbers s, t frequently becomes large due to relationship between the NAND string length and the transfer transistor size. Accordingly, the pattern of the conductive line connecting the transfer transistor to the word line results in a long period and becomes complicated.

### (4) First Embodiment

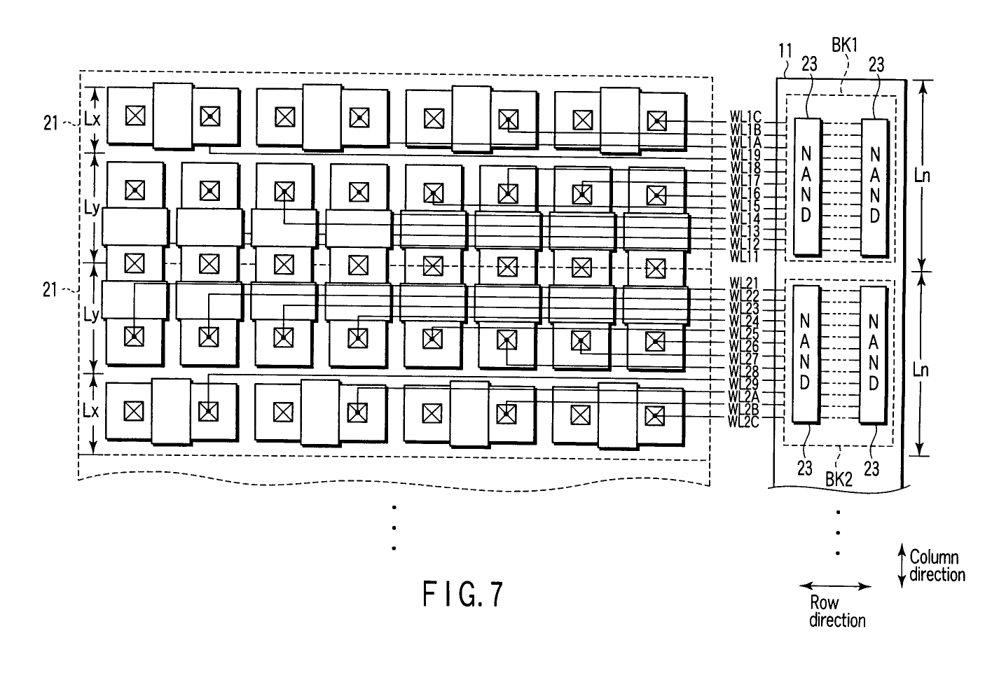

FIG. 7 shows the layout of the transfer transistor in the word line driver as a first embodiment.

A NAND string 23 is comprised 12 memory cells connected serially, and 12 word lines exist in one block.

At one end side of the memory cell array 11, the transfer transistor unit 21 is arranged corresponding to the blocks BK1, BK2 . . . The transfer transistor unit 21 is comprised 2 kinds of transfer transistors in which direction of one transistor is different from that of the other transistor by 90°.

That is, one is the transfer transistor (vertical direction transfer transistor) in which the transfer path (channel length direction) of the transfer voltage is in the column direction, and the other one is the transfer transistor (horizontal direction transfer transistor) in which the transfer path of the transfer voltage is in the row direction.

The transfer transistor unit 21 is comprised 8 vertical direction transfer transistors arranged in the row direction, and 4 horizontal direction transfer transistors arranged in the row direction.

In this layout, for instance, the vertical direction transfer transistor connected to the word lines WL11, . . . , WL18 in the block BK1, and the vertical direction transfer transistor connected to the word lines WL21, . . . , WL28 in the block BK2 share a diffusion layer.

In this manner, like the reference example, the size in the column direction per one transfer transistor decreases, resulting in decreasing the occupied area in the chip of the word line driver.

Here, in the first embodiment, in the case where the size in the column direction of one block is defined as Ln, the size of the channel width direction of the horizontal direction transfer transistor is defined as Lx, and the size of the channel length direction of the vertical direction transfer transistor is defined as Ly, it is necessary to obtain natural numbers s, t, and u which are as small as possible, and sLn which is as close to tLy+uLx as possible on the assumption of fulfilling sLn≧tLy+uLx (s, t and u are natural numbers).

In this case, in comparison with the reference example, one parameter is further added, and its total number becomes 3. Therefore, ideal natural numbers s, t and u are easily obtained.

For instance, as shown in the same drawing, it becomes possible to satisfy 2Ln≧2Ly+2Lx, and to repeat the pattern of the transfer transistor unit 21 and the conductive line connecting the transfer transistor unit 21 to a plurality of word lines WL11, . . . , WL1C, WL21, . . . , WL2C, in every 2Ln with the same pattern.

Therefore, it is possible to simplify the pattern of the conductive line connecting the transfer transistor unit 21 to the plurality of word lines WL11, . . . , WL1C, WL21, . . . , WL2C, and to achieve reduction of the chip size.

Further, the size 2Ln easily becomes approximately the same value as 2Ly+2Lx, and thus it is possible to eliminate a wasteful space and to decrease the occupied area in the chip of the word line driver.

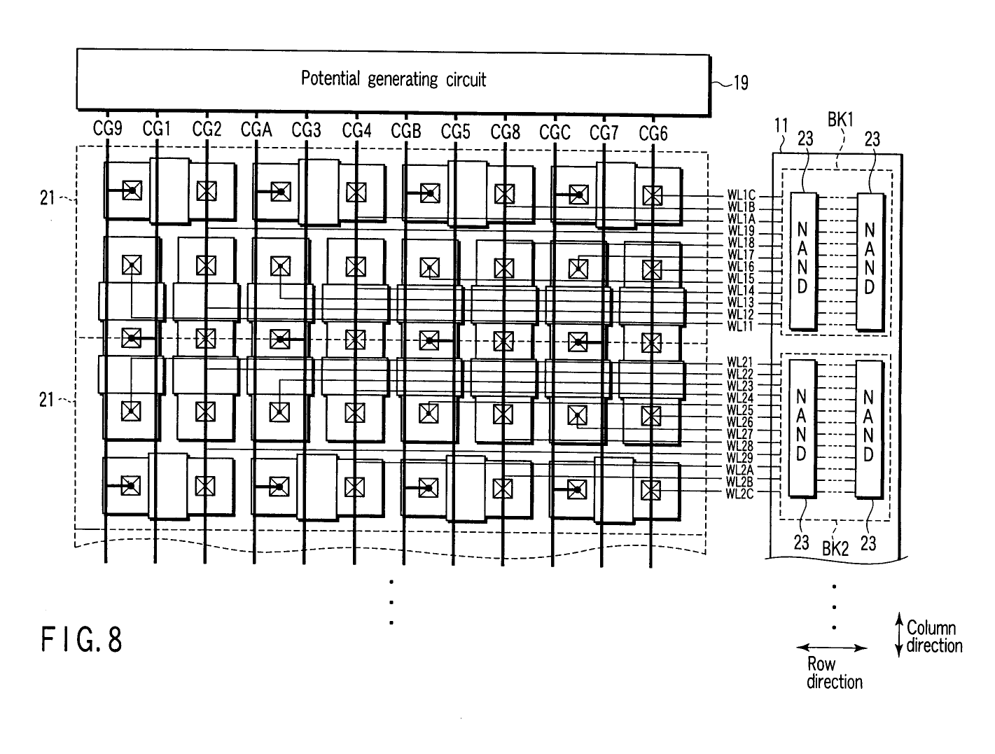

Further, according to the first embodiment, as shown in FIG. 8, the transfer transistor connected to the word lines WL11, . . . , WL1C in the block BK1 and the transfer transistor connected to the word lines WL21, . . . , WL2C in the block BK2 are connected to the conductive lines CG1, . . . , CGC in common, so that the pattern of the conductive lines CG1, . . . , CGC can be simplified.

This is the effect obtained by repeating the pattern of the word line driver (transfer transistor unit) in every small unit, that is, in every 2 blocks (2Ln).

Here, the conductive lines CG1, . . . , CGC are for leading the transfer voltage (write voltage, read voltage, intermediate voltage, or the like) generated at the potential generating circuit 19 to the transfer transistor unit 21.

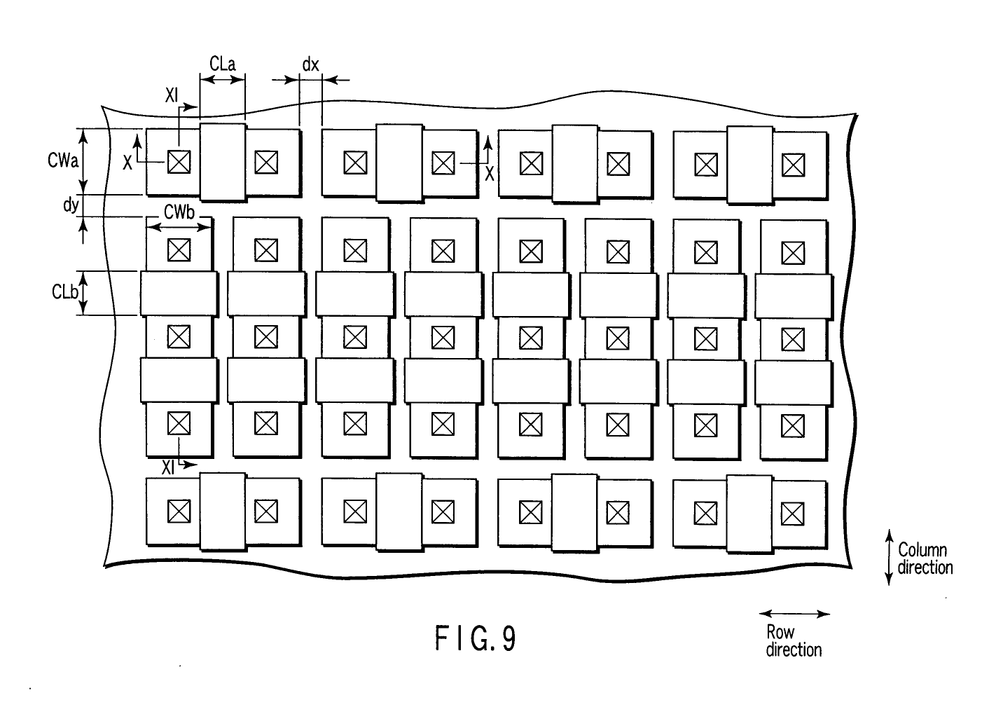

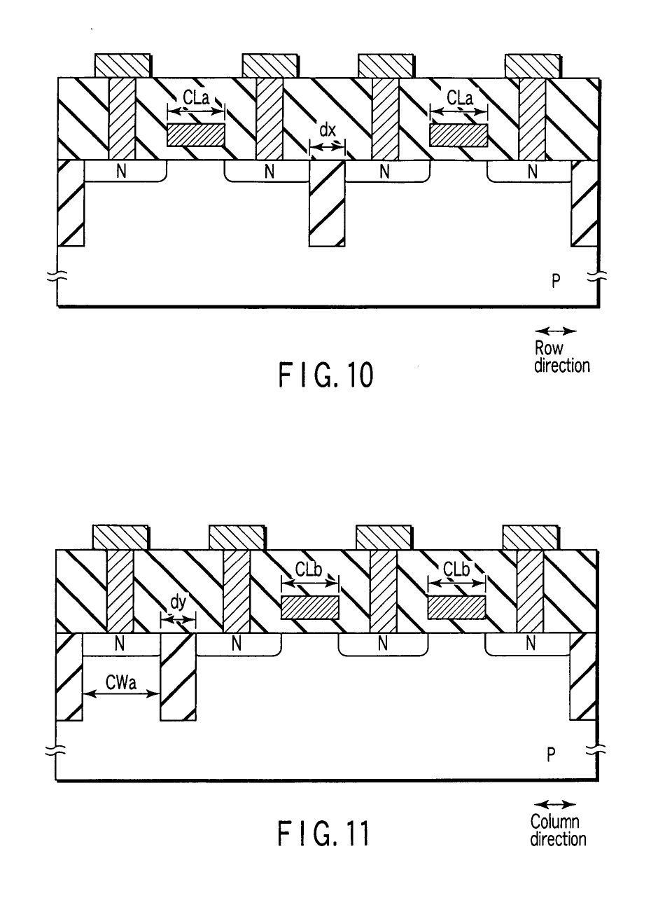

Note that, since it is necessary that characteristic of the whole transfer transistors in the transfer transistor unit 21 is made identical, for instance, as shown in FIGS. 9 to 11, the channel length CLa, CLb and the channel width CWa, CWb of the whole transfer transistors are made identical.

Further, all of the width dx, dy of the element isolation insulating layer are set to the same value to prevent the characteristic of the transfer transistor from being differentiated.

In the first embodiment, although neighboring two vertical direction transfer transistors share the diffusion layer, even the type which does not share the diffusion layer can obtain the same effect.

### (5) Second Embodiment

A second embodiment is a modified example of the first embodiment.

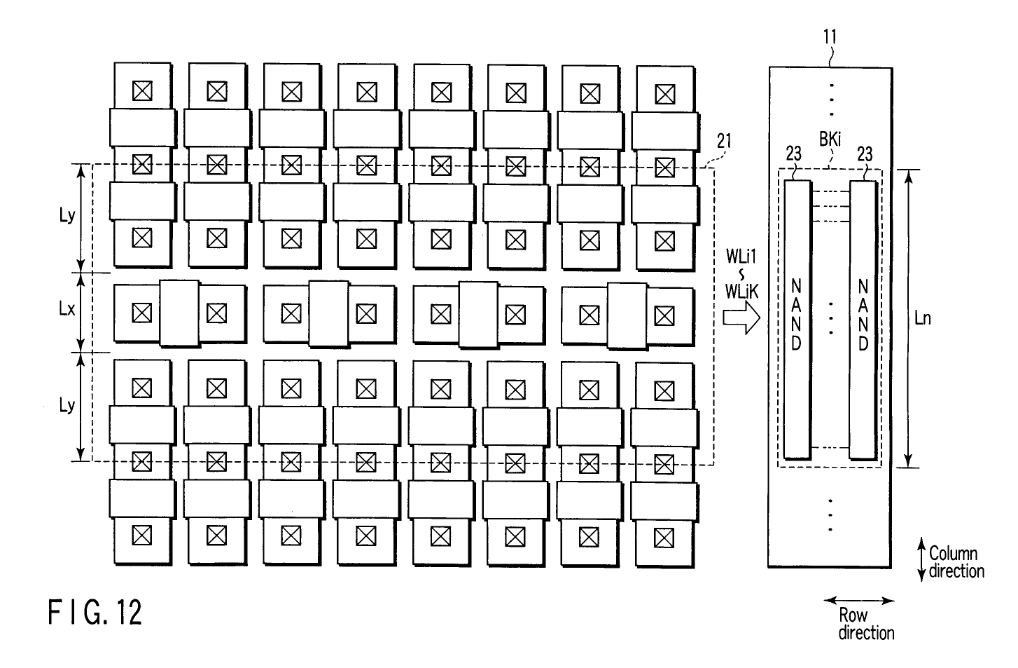

FIG. 12 shows a layout of the transfer transistor in the word line driver as the second embodiment.

The NAND string 23 is comprised 20 memory cells connected serially, and 20 word lines exist in one block.

At one end side of the memory cell array 11, the transfer transistor unit 21 is arranged corresponding to the block BKi.

Like the first embodiment, the transfer transistor unit 21 is comprised two kinds of transfer transistors whose directions are different from each other by 90°, that is, the transfer transistor unit 21 is comprised the vertical direction transfer transistor in which the transfer path (channel length direction) of the transfer voltage is in the column direction and the horizontal direction transfer transistor in which the transfer path of the transfer voltage is in the row direction.

Specifically, the transfer transistor unit 21 is comprised the vertical direction transfer transistors of 8×2 rows arranged in the row direction and 4 horizontal direction transfer transistors arranged in the row direction.

In the second embodiment, for instance, Ln≧2Ly+1Lx is satisfied, and the pattern of the transfer transistor unit 21 and the conductive line connecting the transfer transistor unit 21 to a plurality of word lines WLi1, . . . , WLiK is repeated for each Ln with the same pattern.

Note that Ln is the size in the column direction of one block, Lx is the size in the channel width direction of the horizontal direction transfer transistor, and Ly is the size in the channel length direction of the vertical direction transfer transistor.

Therefore, it is possible to simplify the pattern of the conductive line connecting the transfer transistor unit 21 to the plurality of word lines WLi1, . . . , WLiK, and to achieve reduction of the chip size.

Further, the size Ln easily becomes approximately the same value as 2Ly+1Lx, and thus it is possible to eliminate a wasteful space, and to decrease the occupied area in the chip of the word line driver.

Further, like the first embodiment, the transfer transistors connected to different two blocks can be connected to the conductive lines (corresponding to CG1, . . . , CGC of FIG. 8) supplying the transfer voltage to the transfer transistor in common.

### (6) Third Embodiment

A third embodiment is also the modified example of the first embodiment.

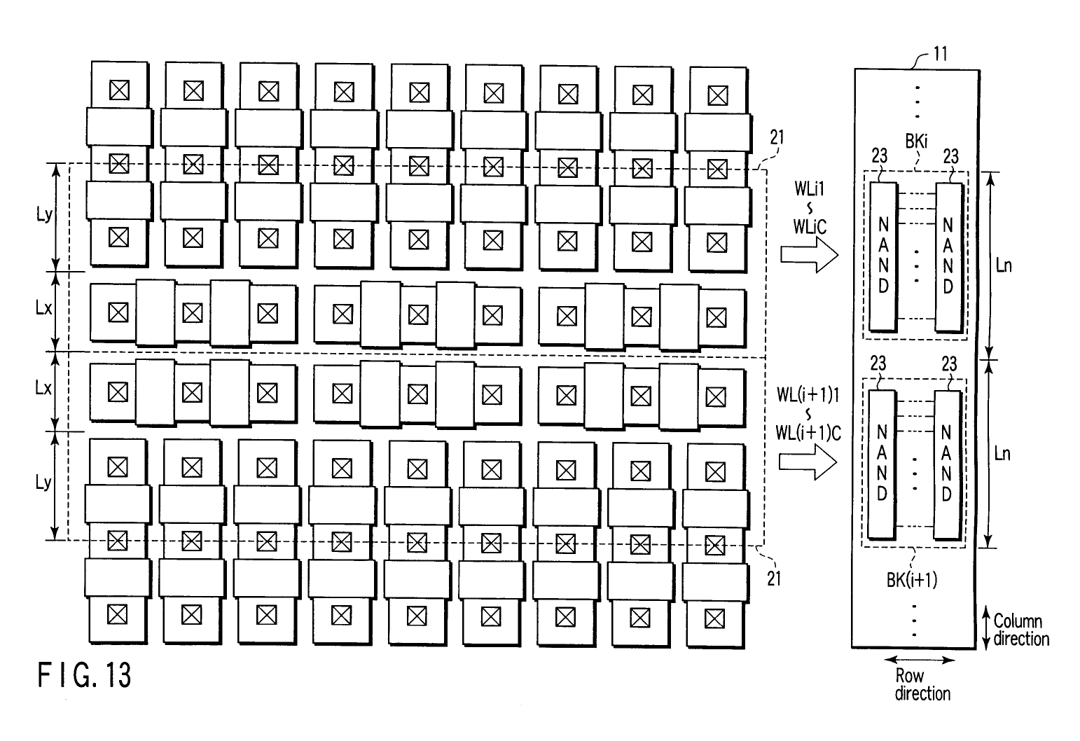

FIG. 13 shows a layout of the transfer transistor in the word line driver as the third embodiment.

The NAND string 23 is comprised 12 memory cells connected serially, and 12 word lines exist in one block.

At one end side of the memory cell array 11, the transfer transistor unit 21 is arranged corresponding to the blocks BKi, BK(i+1).

Like the first embodiment, the transfer transistor unit 21 is comprised two kinds of transfer transistors whose directions are different from each other by 90°, that is, it is comprised the vertical direction transfer transistor in which the transfer path (channel length direction) of the transfer voltage is in the column direction and the horizontal direction transfer transistor in which the transfer path of the transfer voltage is in the row direction.

Specifically, the transfer transistor unit 21 is comprised 9 vertical direction transfer transistors arranged in the row direction and 3 horizontal direction transfer transistors arranged in the row direction.

Unlike the first and second embodiments, the three horizontal direction transfer transistors are of the type in which each of the three horizontal direction transfer transistors and the other horizontal direction transfer transistors share the diffusion layer.

For instance, in the third embodiment, 2Ln≧2Ly+2Lx is satisfied, and the pattern of the transfer transistor unit 21 and the conductive line connecting the transfer transistor unit 21 to a plurality of word lines WLi1, . . . , WLiC, WL(i+1)1, . . . , WL(i+1)C, is repeated in every 2Ln with the same pattern.

Note that Ln is the size in the column direction of one block, Lx is the size in the channel width direction of the horizontal direction transfer transistor, and Ly is the size in the channel length direction of the vertical direction transfer transistor.

Therefore, it is possible to simplify the pattern of the conductive line connecting the transfer transistor unit 21 to the plurality of word lines WLi1, . . . , WLiC, WL(i+1)1, . . . , WL(i+1)C, and to achieve reduction of the chip size.

Further, the size 2Ln easily becomes approximately the same value as 2Ly+2Lx, and thus it is possible to eliminate a wasteful space, and to decrease the occupied area in the chip of the word line driver.

Further, like the first embodiment, the transfer transistors connected to different two blocks can be connected to the conductive lines (corresponding to CG1, . . . , CGC of FIG. 8) supplying the transfer voltage to the transfer transistor in common.

### (7) Fourth Embodiment

A fourth embodiment relates to a layout arranging the word line driver at both ends of the memory cell array.

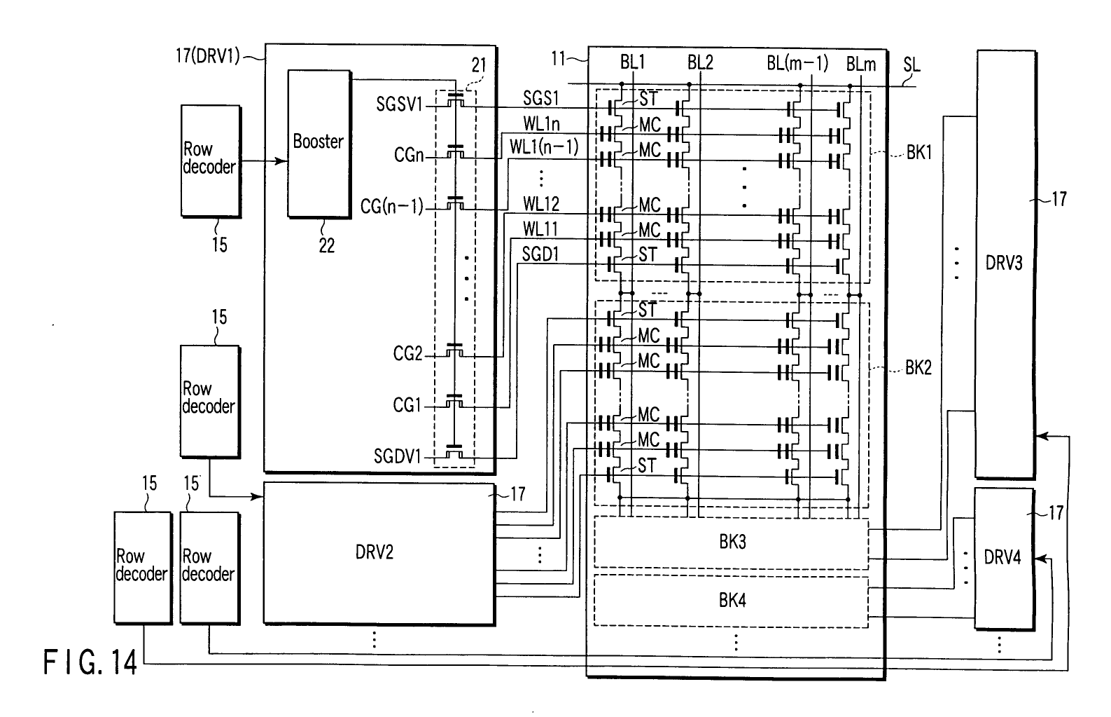

FIG. 14 shows position relationship between the memory cell array and the word line driver.

According to this position relationship, the word line drivers 17 (DRV1, DRV2, . . . ) are arranged at both ends of the memory cell array 11. As a result, in comparison with the example of FIG. 2, room is made in the layout of the transfer transistor unit 21.

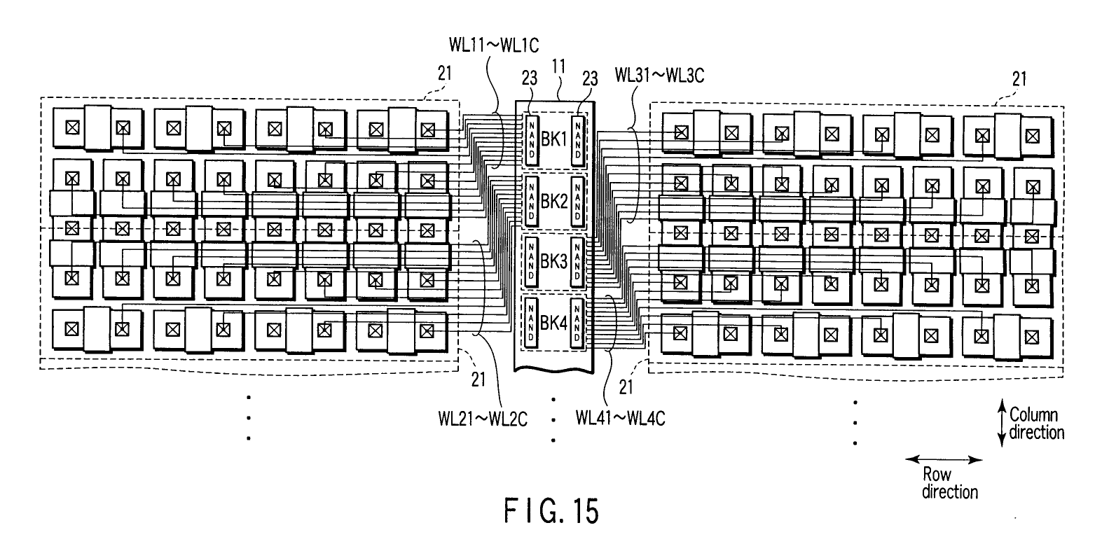

FIG. 15 shows a layout of the transfer transistor in the word line driver as the fourth embodiment.

The NAND string 23 is comprised 12 memory cells connected serially, and 12 word lines exist in one block.

At one end side of the memory cell array 11, the transfer transistor unit 21 is arranged corresponding to the blocks BK1, BK2. Further, at the other end side of the memory cell array 11, the transfer transistor unit 21 is arranged corresponding to the blocks BK3, BK4.

The transfer transistor unit 21 is comprised two kinds of transfer transistors whose directions are different from each other by 90°.

That is, one is the transfer transistor (vertical direction transfer transistor) in which the transfer path (channel length direction) of the transfer voltage is in the column direction, and the other one is the transfer transistor (horizontal direction transfer transistor) in which the transfer path of the transfer voltage is in the row direction.

The transfer transistor unit 21 is comprised 8 vertical direction transfer transistors arranged in the row direction and 4 horizontal direction transfer transistors arranged in the row direction.

In this layout, for instance, the vertical direction transfer transistor connected to the word lines WL11, . . . , WL18 in the block BK1 and the vertical direction transfer transistor connected to the word lines WL21, . . . , WL28 in the block BK2 share the diffusion layer. Therefore, the size in the column direction per one transfer transistor decreases, resulting in decreasing the occupied area in the chip of the word line driver.

Here, in the fourth embodiment, like the first embodiment, in the case where the size in the column direction of one block is defined as Ln, the size of the channel width direction of the horizontal direction transfer transistor is defined as Lx, and the size of the channel length direction of the vertical direction transfer transistor is defined as Ly, it is necessary to obtain natural numbers s, t, and u which are as small as possible, and sLn which is as close to tLy+uLx as possible on the assumption of fulfilling sLn≧tLy+uLx (s, t and u: natural number).

For instance, as shown in the same drawing, 4Ln≧2Ly+2Lx is satisfied, and it becomes possible to repeat the pattern of the transfer transistor unit 21 and the conductive line connecting the transfer transistor unit 21 to a plurality of word lines WL11, . . . , WL1C, WL21, . . . , WL2C, in every 4Ln with the same pattern.

Therefore, it is possible to simplify the pattern of the conductive line connecting the transfer transistor unit 21 to the plurality of word lines WL11, . . . , WL1C, WL21, . . . , WL2C, and to achieve reduction of the chip size.

Further, the size 4Ln easily becomes approximately the same value as 2Ly+2Lx, and thus it is possible to eliminate a wasteful space, and to decrease the occupied area in the chip of the word line driver.

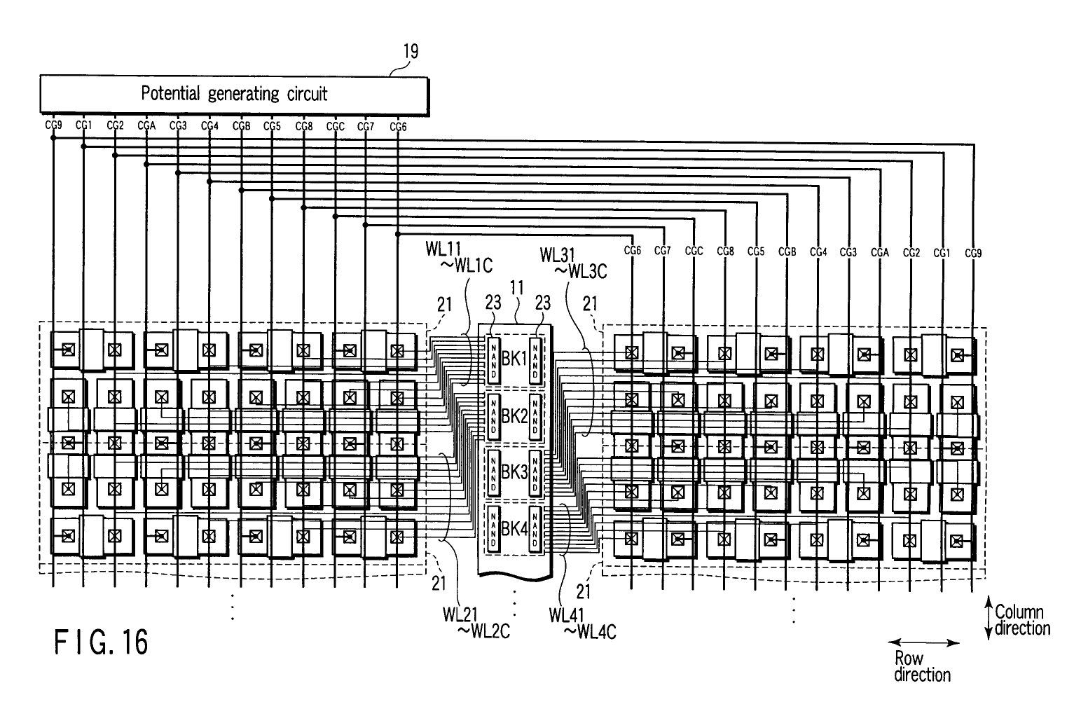

Further, according to the fourth embodiment, as shown in FIG. 16, the transfer transistor connected to the word lines WL11, . . . , WL1C in the block BK1 and the transfer transistor connected to the word lines WL21, . . . , WL2C in the block BK2 are connected to the conductive lines CG1, . . . , CGC in common, so that the pattern of the conductive lines can be simplified.

This is the effect obtained by repeating the pattern of the word line driver (transfer transistor unit) in every small unit, that is, in every 4 blocks (4Ln).

Note that, since it is necessary that characteristic of the whole transfer transistors in the transfer transistor unit 21 is made identical, as shown in FIGS. 9 to 11, the channel length CLa, CLb and the channel width CWa, CWb of the whole transfer transistors are made identical.

Further, all of the width dx, dy of the element isolation insulating layer are set to the same value to prevent the characteristics of the transfer transistors from being differentiated.

In the fourth embodiment, neighboring two vertical direction transfer transistors share the diffusion layer. However, even the type which does not share the diffusion layer can obtain the same effect.

### (8) Fifth Embodiment

A fifth embodiment is the modified example of the fourth embodiment.

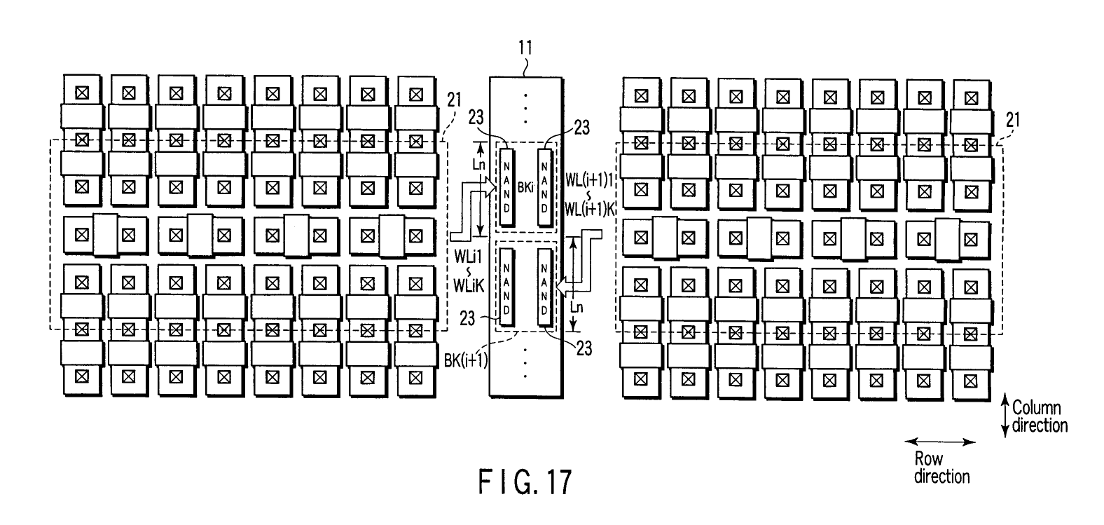

FIG. 17 shows a layout of the transfer transistor in the word line driver as the fifth embodiment.

The NAND string 23 is comprised 20 memory cells connected serially, and 20 word lines exist in one block.

At one end side of the memory cell array 11, the transfer transistor unit 21 is arranged corresponding to the block BKi. At the other end side of the memory cell array 11, the transfer transistor unit 21 is arranged corresponding to the block BK(i+1).

Like the fourth embodiment, the transfer transistor unit 21 is comprised two kinds of transfer transistors whose directions are different from each other by 90°, that is, it is comprised the vertical direction transfer transistor in which the transfer path (channel length direction) of the transfer voltage is in the column direction and the horizontal direction transfer transistor in which transfer path of the transfer voltage is in the row direction.

Specifically, the transfer transistor unit 21 is comprised the vertical direction transfer transistors of 8×2 rows arranged in the row direction and 4 horizontal direction transfer transistors arranged in the row direction.

For instance, in the fifth embodiment, 2Ln≧2Ly+1Lx is satisfied, and the pattern of the transfer transistor unit 21 and the conductive line connecting the transfer transistor unit 21 to a plurality of word lines WL11, . . . , WL1K, WL21, . . . , WL2K is repeated in every 2Ln with the same pattern.

Note that Ln is the size in the column direction of one block, Lx is the size in the channel width direction of the horizontal direction transfer transistor, and Ly is the size in the channel length direction of the vertical direction transfer transistor.

Therefore, it is possible to simplify the pattern of the conductive line connecting the transfer transistor unit 21 to the plurality of word lines WL11, . . . , WL1K, WL21, . . . , WL2K, and to achieve reduction of the chip size.

Further, the size 2Ln easily becomes approximately the same value as 2Ly+1Lx, and thus it is possible to eliminate a wasteful space, and to decrease the occupied area in the chip of the word line driver.

Further, like the fourth embodiment, the transfer transistors connected to different two blocks can be connected to the conductive lines (corresponding to CG1, . . . , CGC of FIG. 16) supplying the transfer voltage to the transfer transistor in common.

### (9) Sixth Embodiment

A sixth embodiment is also the modified example of the fourth embodiment.

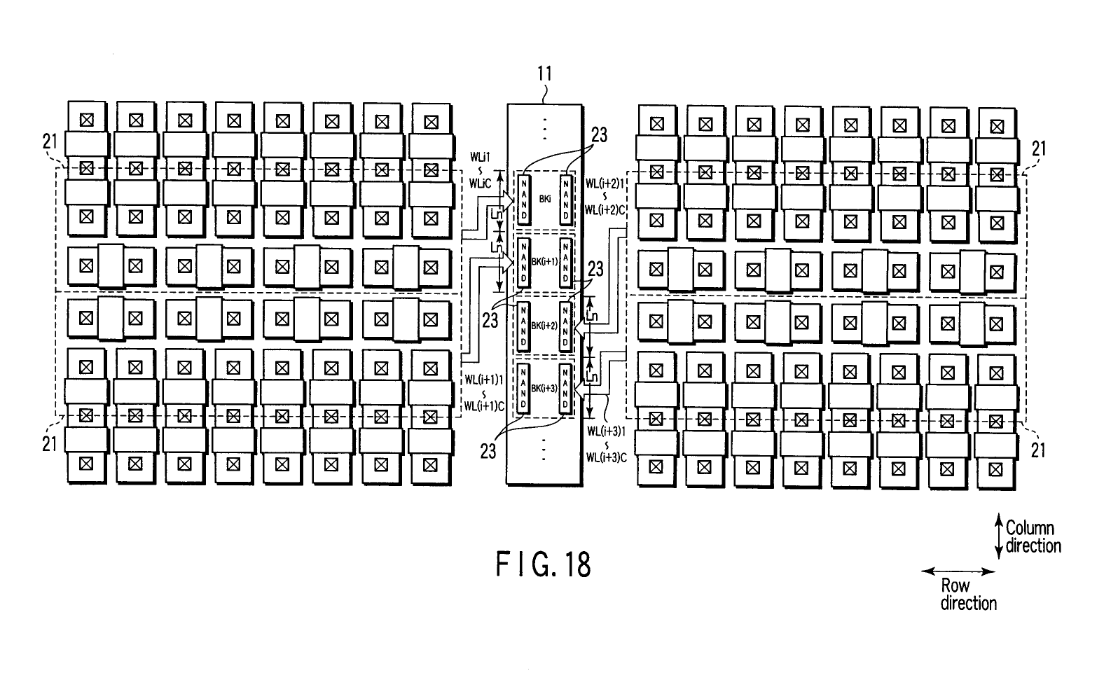

FIG. 18 shows a layout of the transfer transistor in the word line driver as the sixth embodiment.

The NAND string 23 is comprised 12 memory cells connected serially, and 12 word lines exist in one block.

At one end side of the memory cell array 11, the transfer transistor unit 21 is arranged corresponding to the blocks BKi, BK(i+1). At the other end side of the memory cell array 11, the transfer transistor unit 21 is arranged corresponding to the blocks BK(i+2), BK(i+3).

Like the fourth embodiment, the transfer transistor unit 21 is comprised two kinds of transfer transistors whose directions are different from each other by 90°, that is, it is comprised the vertical direction transfer transistor in which the transfer path (channel length direction) of the transfer voltage is in the column direction and the horizontal direction transfer transistor in which the transfer path of the transfer voltage is in the row direction.

Specifically, the transfer transistor unit 21 is comprised 9 vertical direction transfer transistors arranged in the row direction and 3 horizontal direction transfer transistors arranged in the row direction.

Unlike the fourth and fifth embodiments, the three horizontal direction transfer transistors are of the type in which each of the three horizontal direction transfer transistors and the other horizontal direction transfer transistors share the diffusion layer.

For instance, in the sixth embodiment, 4Ln≧2Ly+2Lx is satisfied, and the pattern of the transfer transistor unit 21 and the conductive line connecting the transfer transistor unit 21 to a plurality of word lines WL11, . . . , WL1C, WL21, . . . , WL2C is repeated in every 4Ln with the same pattern.

Note that Ln is the size in the column direction of one block, Lx is the size in the channel width direction of the horizontal direction transfer transistor, and Ly is the size in the channel length direction of the vertical direction transfer transistor.

Therefore, it is possible to simplify the pattern of the conductive line connecting the transfer transistor unit 21 to the plurality of word lines WL11, . . . , WL1C, WL21, . . . , WL2C and to achieve reduction of the chip size.

Further, the size 4Ln easily becomes approximately the same value as 2Ly+2Lx, and thus it is possible to eliminate a wasteful space, and to decrease the occupied area in the chip of the word line driver.

Further, like the fourth embodiment, the transfer transistors connected to different two blocks can be connected to the conductive lines (corresponding to CG1, . . . , CGC of FIG. 16) supplying the transfer voltage to the transfer transistor in common.

### (6) Others

The above embodiments have been described with respect to the NAND-type flash memory. However, the examples of the present invention, without being limited thereto, can be generally applied to the semiconductor memory including volatile memories such as dynamic random access memory (DRAM), static random access memory (SRAM) and the like, and non-volatile memories such as NOR-type flash memory, ferroelectric random access memory (FeRAM), magnetic random access memory (MRAM) and the like.

In the NAND-type flash memory, although the transfer transistor unit is arranged corresponding to each block, the block itself is a group including a plurality of word lines. Thus, in the case where the example of the present invention is generally applied to the semiconductor memory, the transfer transistor unit may be preferably arranged corresponding to each group including a plurality of word lines.

### 3. CONCLUSION

According to the examples of the present invention, connection between the word line and the word line driver is simplified with a new layout of the word line driver, making it possible to reduce the chip size.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory comprising:
a memory cell array;
word lines extending in a first direction on the memory cell array; and
transfer transistors each one of which is connected to each of the word lines, and which transfer a transfer voltage,
wherein a direction of one of the transfer transistors is different from a direction of another one of the transfer transistors.

2. The semiconductor memory according to claim 1,
wherein a direction of one of the transfer transistors is different from a direction of the another one of the transfer transistors by 90°.

3. The semiconductor memory according to claim 1,
wherein the word lines are comprised first and second groups, the transfer transistor connected to the word line in the first group and the transfer transistor connected to the word line in the second group are connected to a conductive line in common, and the conductive line supplies the transfer voltage.

4. The semiconductor memory according to claim 1,
wherein the word lines are comprised first and second groups, each of the transfer transistors is a MISFET, and the transfer transistor connected to the word line in the first group and the transfer transistor connected to the word line in the second group share a diffusion layer.

5. The semiconductor memory according to claim 1,
wherein the word lines are comprised first and second groups, the transfer transistor connected to the word line in the first group is provided at one end side of the memory cell array, and the transfer transistor connected to the word line in the second group is provided at other end side of the memory cell array.

6. The semiconductor memory according to claim 1,
wherein the word lines are comprised first and second groups which are adjacent in a second direction perpendicular to the first direction,
each of the transfer transistors is a MISFET, and
sLn≧tLy+uLx (s, t, and u are natural numbers) is satisfied, and a pattern of the transfer transistors and a pattern of conductive lines connecting the transfer transistors to the word lines are repeated every sLn with the same pattern, in a case where a size in the second direction of each group is Ln, a size in a channel width direction of each of the transfer transistors is Lx, and a size in a channel length direction of each of the transfer transistors is Ly.

7. The semiconductor memory according to claim 1,
wherein the memory cell array is comprised NAND cell units.

8. The semiconductor memory according to claim 1,
wherein each of the transfer transistors is comprised a high voltage type MISFET.

9. The semiconductor memory according to claim 1,
wherein the transfer transistors are comprised an array.

10. The semiconductor memory according to claim 1,
wherein the word lines are provided in one NAND block.

11. A NAND-type flash memory comprising:
first and second NAND cell units comprised memory cells connected in series and two select gate transistors sandwiched the memory cells;
a first NAND block having the first NAND cell unit;
a second NAND block having the second NAND cell unit;
word lines provided in the first and second NAND blocks and extending in a first direction; and
transfer transistors each one of which is connected to each of the word lines, and which transfer a transfer voltage,
wherein a direction of one of the transfer transistors is different from a direction of another one of the transfer transistors.

12. The NAND-type flash memory according to claim 11,
wherein a direction of one of the transfer transistors is different from a direction of the another one of the transfer transistors by 90°.

13. The NAND-type flash memory according to claim 11,
wherein the transfer transistor connected to the word line in the first NAND block and the transfer transistor connected to the word line in the second NAND block are connected to a conductive line in common, and the conductive line supply the transfer voltage.

14. The NAND-type flash memory according to claim 11,
wherein each of the transfer transistors is a MISFET, and the transfer transistor connected to the word line in the first NAND block and the transfer transistor connected to the word line in the second NAND block share a diffusion layer.

15. The NAND-type flash memory according to claim 11,
wherein the transfer transistor connected to the word line in the first NAND block is provided at one end side of the memory cell array, and the transfer transistor connected to the word line in the second NAND block is provided at other end side of the memory cell array.

16. The NAND-type flash memory according to claim 11,
wherein each of the transfer transistors is a MISFET, and
sLn≧tLy+uLx (s, t, and u are natural numbers) is satisfied, and a pattern of the transfer transistors and a pattern of conductive lines connecting the transfer transistors to the word lines are repeated every sLn with the same pattern, in a case where a size in a second direction perpendicular to the first direction of the first and second NAND blocks is Ln, a size in a channel width direction of the transfer transistors is Lx, and a size in a channel length direction of the transfer transistors is Ly.

17. The NAND-type flash memory according to claim 11,
wherein a direction of the transfer transistor connected to one word line in the first NAND block is different from a direction of the transfer transistor connected to another one word line in the first NAND block by 90°.

18. The NAND-type flash memory according to claim 11,
wherein each of the first and second NAND blocks is comprised NAND cell units.

19. The NAND-type flash memory according to claim 11,
wherein each of the transfer transistors is a high voltage type MISFET.

20. The NAND-type flash memory according to claim 11,
wherein the transfer transistors are comprised an array.
